(19) United States
(12) Patent Application Publication
(10) Pub. No.: US 2026/0147268 A1
(43) Pub. Date: May 28, 2026

(54) SUBSTRATE WITH CONDUCTIVE FILM, REFLECTIVE MASK BLANK, REFLECTIVE MASK, AND METHOD FOR MANUFACTURING SEMICONDUCTOR DEVICE

(71) Applicant: HOYA CORPORATION, Tokyo (JP)

(72) Inventors: Hibiki KISHIDA, Tokyo (JP); Masanori NAKAGAWA, Tokyo (JP)

(73) Assignee: HOYA CORPORATION, Tokyo (JP)

(21) Appl. No.: 19/114,655

(22) PCT Filed: Sep. 25, 2023
(86) PCT No.: PCT/JP2023/034697

§ 371 Date: Mar. 24, 2025

(30) Foreign Application Priority Data
Sep. 28, 2022 (JP) 2022-154690

(51) Int. Cl. G03F 1/24

(52) U.S. Cl. CPC G03F 1/24

(57) ABSTRACT

Provided is a substrate with a conductive film capable of suppressing a change in flatness in a reflective mask with a conductive film for EUV lithography and a reflective mask blank with a conductive film for EUV lithography.

The substrate with a conductive film comprises: a substrate having two main surfaces; and a conductive film disposed on one of the main surfaces of the substrate. The conductive film comprises an outermost layer disposed on an outermost surface of the conductive film on a side opposite to the substrate, and a conductive layer disposed between the outermost layer and the substrate. The outermost layer comprises a metal (M), boron (B), and oxygen (O). The outermost layer has a maximum peak at binding energy of 190 eV or more and 195 eV or less in a B1s narrow spectrum obtained by analysis by X-ray photoelectron spectroscopy.

### TECHNICAL FIELD

The present invention relates to a substrate with a conductive film to be used for EUV lithography, a reflective mask blank, a reflective mask, and a method for manufacturing a semiconductor device.

### BACKGROUND ART

In recent years, in the semiconductor industry, along with high integration of a semiconductor device, a fine pattern exceeding a transfer limit of a conventional photolithography method using ultraviolet light has been required. In order to make such fine pattern formation possible, extreme ultraviolet (hereinafter, referred to as “EUV”) lithography, which is an exposure technique using EUV light, is promising. Here, the EUV light refers to light in a wavelength band of a soft X-ray region or a vacuum ultraviolet region, and is specifically light having a wavelength of about 0.2 to 100 nm. A reflective mask has been proposed as a transfer mask used in this EUV lithography. In such a reflective mask, a multilayer reflective film that reflects exposure light is formed on a substrate, and an absorber film that absorbs exposure light is formed in a pattern shape on the multilayer reflective film.

The reflective mask is manufactured by forming an absorber film pattern by a photolithography method or the like from a reflective mask blank including a substrate, a multilayer reflective film formed on the substrate, and an absorber film formed on the multilayer reflective film.

The multilayer reflective film and an absorption layer are generally formed using a film forming method such as sputtering. At the time of film formation, a substrate for a reflective mask blank is supported by a support means in a film forming apparatus. An electrostatic chuck is used as one of means for supporting the substrate. In addition, an electrostatic chuck is used to fix a reflective mask in an exposure apparatus at the time of exposure with EUV light. Therefore, a conductive film (conductive back film) is formed on a back surface (surface opposite to a surface on which a multilayer reflective film or the like is formed) of an insulating substrate for a reflective mask blank, such as a glass substrate, in order to promote fixing of the substrate by an electrostatic chuck. The substrate on which the conductive film is formed is referred to as a substrate with a conductive film.

As an example of the substrate with a conductive film, Patent Document 1 describes a substrate with a multilayer reflective film for EUV lithography, in which a multilayer reflective film that reflects EUV light is formed on a glass substrate, and furthermore, a conductive film is formed on a surface opposite to the surface where the multilayer reflective film is formed. Patent Document 1 describes that the conductive film is made of a material containing tantalum and substantially containing no hydrogen. In addition, Patent Document 1 describes that the substrate with a multilayer reflective film of Patent Document 1 includes a hydrogen intrusion suppressing film that suppresses intrusion of hydrogen from the glass substrate into the conductive film between the glass substrate and the conductive film.

Patent Document 2 describes a substrate for a photolithography mask, including a coating deposited on a rear surface of the substrate. Patent Document 2 describes that the coating includes at least one conductive layer, and the thickness of the at least one layer is smaller than 30 nm.

### PRIOR ART DOCUMENTS

### Patent Documents

Patent Document 1: JP 2013-225662 A
Patent Document 2: JP 2014-532313 A

### DISCLOSURE OF INVENTION

A requirement level of defect quality for a reflective mask blank and a reflective mask has become severer year by year. In manufacturing a reflective mask blank and manufacturing a semiconductor device using a reflective mask, the reflective mask blank and the reflective mask are repeatedly attached to and detached from an electrostatic chuck. At this time, rubbing occurs between a conductive film of each of the reflective mask blank and the reflective mask and the electrostatic chuck. Therefore, after the reflective mask blank and the reflective mask are detached from the electrostatic chuck, a surface of the conductive film is usually cleaned with a chemical solution using an acid or an alkali. As a material of the conductive film, a material containing tantalum (Ta) having high chemical resistance and abrasion resistance has attracted attention.

In addition, in recent years, a requirement level of pattern position accuracy for a transfer mask such as a reflective mask has become particularly severe. In particular, in a case of a reflective mask for EUV lithography, since the reflective mask is used for the purpose of forming a very fine pattern as compared with prior art, the required level of pattern position accuracy is more severe. One factor for achieving high pattern position accuracy is to improve a flatness of a reflective mask blank to be an original plate for preparing a reflective mask.

In Patent Document 1, the conductive film is made of a material containing tantalum and substantially containing no hydrogen, and a hydrogen intrusion suppressing film that suppresses intrusion of hydrogen from the glass substrate into the conductive film is included between the glass substrate and the conductive film, whereby a reflective mask blank that suppresses a change with time in flatness can be obtained.

By the way, in an EUV exposure apparatus that transfers an integrated circuit pattern onto a semiconductor substrate by EUV light reflected by a reflective mask, since EUV light is strongly absorbed by gas molecules, it is generally necessary to keep the inside of an optical system container at a high vacuum. However, impurities such as moisture and a hydrocarbon cannot be completely eliminated even in high vacuum, and when these impurities are exposed to EUV light, a carbon film or the like is deposited on a mirror surface of an irradiation optical system, resulting in a decrease in reflectance. In the EUV exposure apparatus, exposure in a hydrogen atmosphere having high EUV light transmittance is performed in order to suppress such contamination. In such an exposure environment in a hydrogen atmosphere, when a reflective mask is repeatedly used for manufacturing a semiconductor device, it has become clear that there may be a problem that hydrogen intrudes also from a surface of a conductive film to change a flatness of the reflective mask.

The present invention has been made under such a circumstance, and an object thereof is to provide a reflective mask blank and a reflective mask capable of suppressing a change in flatness in a reflective mask blank with a conductive film and a reflective mask with a conductive film. Another object of the present invention is to provide a substrate with a conductive film for manufacturing a reflective mask blank and a reflective mask for solving the above problem. In addition, another object of the present invention is to provide a method for manufacturing a highly accurate semiconductor device by using the above reflective mask.

In order to solve the above problem, the present embodiment has the following configurations.

### (Configuration 1)

Configuration 1 is a substrate with a conductive film, comprising:
a substrate having two main surfaces; and
a conductive film disposed on one of the main surfaces of the substrate, in which
the conductive film comprises an outermost layer disposed on an outermost surface of the conductive film on a side opposite to the substrate, and a conductive layer disposed between the outermost layer and the substrate,
the outermost layer comprises a metal (M), boron (B), and oxygen (O), and
the outermost layer has a maximum peak at binding energy of 190 eV or more and 195 eV or less in a B1s narrow spectrum obtained by analysis by X-ray photoelectron spectroscopy.

### (Configuration 2)

Configuration 2 is the substrate with a conductive film according to configuration 1, in which a detection depth of the X-ray photoelectron spectroscopy in the outermost layer is about 4 to 5 nm.

### (Configuration 3)

Configuration 3 is the substrate with a conductive film according to configuration 1 or 2, in which the outermost layer has no peak at binding energy of 185 eV or more and less than 190 eV in a B1s narrow spectrum obtained by analysis by the X-ray photoelectron spectroscopy.

### (Configuration 4)

Configuration 4 is the substrate with a conductive film according to any one of configurations 1 to 3, in which the content of boron (B) in the outermost layer is 0.5 to 25 at %.

### (Configuration 5)

Configuration 5 is the substrate with a conductive film according to any one of configurations 1 to 4, in which the conductive layer comprises the metal (M) and boron (B).

### (Configuration 6)

Configuration 6 is the substrate with a conductive film according to any one of configurations 1 to 5, in which the conductive layer has a maximum peak at binding energy of 185 eV or more and less than 190 eV in a B1s narrow spectrum obtained by analysis by the X-ray photoelectron spectroscopy.

### (Configuration 7)

Configuration 7 is the substrate with a conductive film according to any one of configurations 1 to 6, in which the metal (M) is at least one selected from Ta, Cr, Pt, Au, Rh, Ru, Ir, and Hf.

### (Configuration 8)

Configuration 8 is a reflective mask blank comprising:
the substrate with a conductive film according to any one of configurations 1 to 7;
a multilayer reflective film disposed on the other main surface of the substrate; and
an absorber film disposed on the multilayer reflective film.

### (Configuration 9)

Configuration 9 is a reflective mask comprising an absorber pattern in which a pattern is formed on the absorber film in the reflective mask blank according to configuration 8.

### (Configuration 10)

Configuration 10 is a method for manufacturing a semiconductor device, comprising performing a lithography process with an exposure apparatus using the reflective mask according to configuration 9 to form a transfer pattern on a transferred object.

According to the present invention, it is possible to provide a reflective mask blank and a reflective mask capable of suppressing a change in flatness in a reflective mask blank with a conductive film for EUV lithography and a reflective mask with a conductive film for EUV lithography. In addition, according to the present invention, it is possible to provide a substrate with a conductive film for manufacturing a reflective mask blank and a reflective mask for solving the above problem. In addition, by using the reflective mask of the present invention, it is possible to provide a method for manufacturing a highly accurate semiconductor device.

### BRIEF DESCRIPTION OF DRAWINGS

FIG. 1 is a schematic cross-sectional view illustrating an example of a configuration of a substrate with a conductive film of the present embodiment.

FIG. 2 is a schematic cross-sectional view illustrating an example of the configuration of the substrate with a conductive film (substrate with a multilayer reflective film) of the present embodiment.

FIG. 3 is a schematic cross-sectional view illustrating an example of the configuration of the substrate with a conductive film (substrate with a multilayer reflective film) of the present embodiment.

FIG. 4 is a schematic cross-sectional view illustrating an example of a configuration of a reflective mask blank of the present embodiment.

FIG. 5 is a schematic cross-sectional view illustrating an example of the configuration of the reflective mask blank of the present embodiment.

FIG. 6 is a schematic cross-sectional view illustrating an example of a method for manufacturing a reflective mask of the present embodiment.

FIG. 7 is a schematic diagram illustrating an example of an EUV exposure apparatus.

FIG. 8 is a diagram illustrating a B1s narrow spectrum of a conductive film of a substrate with a conductive film in each of Example 1 and Comparative Example 1 of the present embodiment, obtained by analysis by X-ray photoelectron spectroscopy.

### DESCRIPTION OF EMBODIMENTS

Hereinafter, an embodiment of the present invention will be specifically described. Note that the following embodiment is one mode for embodying the present invention and does not limit the present invention within the scope thereof.

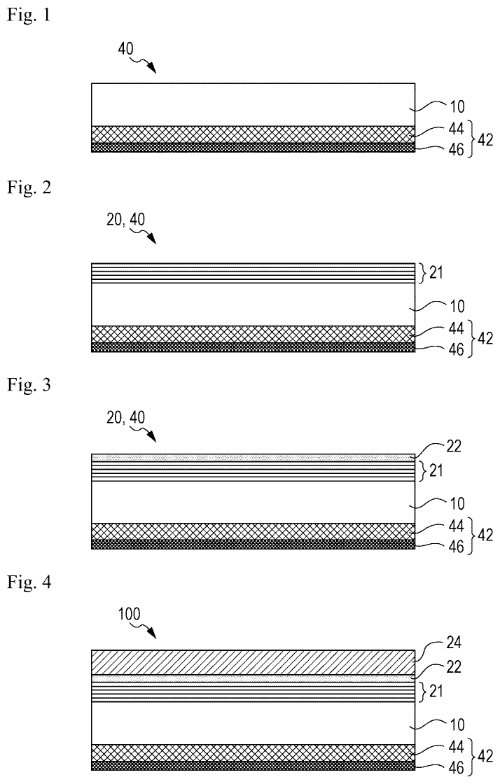

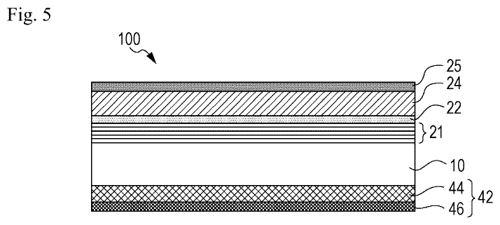

FIG. 1 is a schematic cross-sectional view illustrating an example of a substrate with a conductive film 40 of the present embodiment. The substrate with a conductive film 40 of the present embodiment has a structure in which a conductive film 42 is disposed on one main surface (second main surface or back surface) of a substrate 10. Note that, in the present specification, the substrate with a conductive film 40 is a substrate in which the conductive film 42 is formed on at least one main surface (second main surface or back surface) of the substrate 10, and a substrate with a multilayer reflective film 20 (see FIGS. 2 and 3) in which a multilayer reflective film 21 is formed on the other main surface (first main surface or front surface), a reflective mask blank 100 (see FIGS. 4 and 5) in which an absorber film 24 is further formed, and the like are also included in the substrate with a conductive film 40. In the present specification, the conductive film 42 may be referred to as a conductive back film.

FIG. 2 illustrates an example of the substrate with a multilayer reflective film 20. The multilayer reflective film 21 is formed on the first main surface of the substrate 10 of the substrate with a multilayer reflective film 20 illustrated in FIG. 2. The conductive film 42 is formed on the second main surface (back surface) of the substrate 10 of the substrate with a multilayer reflective film 20 illustrated in FIG. 2. The substrate with a multilayer reflective film 20 illustrated in FIG. 2 includes the conductive film 42 on the second main surface (back surface) of the substrate 10, and thus is a type of the substrate with a conductive film 40.

FIG. 3 illustrates another example of the substrate with a multilayer reflective film 20. The multilayer reflective film 21 and a protective film 22 are formed on a main surface of the substrate with a multilayer reflective film 20 illustrated in FIG. 3. The conductive film 42 is formed on the second main surface (back surface) of the substrate 10 of the substrate with a multilayer reflective film 20 illustrated in FIG. 3. The substrate with a multilayer reflective film 20 illustrated in FIG. 3 includes the conductive film 42 on the second main surface (back surface) of the substrate 10, and thus is a type of the substrate with a conductive film 40.

FIG. 4 is a schematic cross-sectional view illustrating an example of the reflective mask blank 100 of the present embodiment. The reflective mask blank 100 of FIG. 4 includes the multilayer reflective film 21, the protective film 22, and the absorber film 24. In addition, the reflective mask blank 100 illustrated in FIG. 4 includes the conductive film 42 on the second main surface (back surface). Therefore, the reflective mask blank 100 illustrated in FIG. 4 is a type of the substrate with a conductive film 40.

FIG. 5 is a schematic cross-sectional view illustrating another example of the reflective mask blank 100 of the present embodiment. The reflective mask blank 100 illustrated in FIG. 5 includes an etching mask film 25 on the absorber film 24. In a case where the reflective mask blank 100 including the etching mask film 25 is used, the etching mask film 25 may be peeled off after a transfer pattern is formed on the absorber film 24 as described later. In addition, the reflective mask blank 100 of the present embodiment includes the conductive film 42 on a back surface thereof. Therefore, the reflective mask blank 100 illustrated in FIG. 5 is a type of the substrate with a conductive film 40.

In addition, in the reflective mask blank 100 illustrated in FIG. 4 in which the etching mask film 25 is not formed, the absorber film 24 may have a stack formed of a plurality of layers, materials constituting the plurality of layers may have etching characteristics different from each other, and the reflective mask blank 100 in which the absorber film 24 has an etching mask function may be thereby formed.

In the present specification, “a thin film B is disposed (formed) on a thin film A (or substrate 10)” includes not only a case where the thin film B is disposed (formed) in contact with a surface of the thin film A (or substrate 10) but also a case where there is another thin film C between the thin film A (or substrate 10) and the thin film B. In addition, in the present specification, for example, “a thin film B is disposed in contact with a surface of a thin film A (or substrate 10)” means that the thin film A (or substrate 10) and the thin film B are disposed in direct contact with each other without another thin film interposed between the thin film A (or substrate 10) and the thin film B. In addition, in the present specification, “on” does not necessarily mean an upper side in the vertical direction. “On” merely indicates a relative positional relationship among a thin film, the substrate 10, and the like.

The substrate with a conductive film 40, the substrate with a multilayer reflective film 20, the reflective mask blank 100, and the reflective mask 200 of the present embodiment will be specifically described.

### [Substrate 10]

First, the substrate 10 that can be used for manufacturing the substrate with a conductive film 40 and the like of the present embodiment will be described below.

As the substrate 10, a substrate having a low thermal expansion coefficient within a range of 0±5 ppb/° C. is preferably used in order to prevent distortion of a transfer pattern due to heat during exposure to EUV light. As a material having a low thermal expansion coefficient within this range, for example, SiO₂—TiO₂-based glass, multicomponent-based glass ceramic, or the like can be used.

A main surface (first main surface) of the substrate 10 on a side where a transfer pattern (absorber pattern 24a described later) is formed is preferably processed in order to increase a flatness. By increasing the flatness of the main surface of the substrate 10, position accuracy and transfer accuracy of a pattern can be increased. For example, in a case of EUV exposure, the flatness in a region of 132 mm×132 mm of the first main surface is preferably 0.1 μm or less, more preferably 0.05 μm or less, and particularly preferably 0.03 μm or less. In addition, a second main surface (back surface) opposite to the side where the transfer pattern is formed is a surface to be fixed to an exposure apparatus by an electrostatic chuck. The flatness in a region of 142 mm×142 mm of the back surface is preferably 0.1 μm or less, more preferably 0.05 μm or less, and particularly preferably 0.03 μm or less. Note that, in the present specification, the flatness is a value representing warpage (deformation amount) of a surface indicated by total indicated reading (TIR). The flatness (TIR) is an absolute value of a difference in height between the highest position of a surface of the substrate 10 above a focal plane and the lowest position of the surface of the substrate 10 below the focal plane, in which the focal plane is a plane defined by a minimum square method using a main surface of the substrate 10 as a reference.

In a case of EUV exposure, the first main surface of the substrate 10 on a side where the transfer pattern is formed preferably has a surface roughness of 0.1 nm or less in terms of root mean square roughness (Rq). Note that the surface roughness can be measured with an atomic force microscope.

The substrate 10 preferably has a high rigidity in order to prevent deformation of a thin film (such as the multilayer reflective film 21) formed on the substrate 10 due to a film stress. In particular, the substrate 1 preferably has a high Young's modulus of 65 GPa or more.

[Substrate with a Conductive Film 40]

Next, the substrate with a conductive film 40 of the present embodiment will be described.

### <Conductive Film 42>

As illustrated in FIG. 1, the substrate with a conductive film 40 of the present embodiment has a structure in which the predetermined conductive film 42 is disposed on one main surface (second main surface or back surface) of the substrate 10. The conductive film 42 (conductive back film) is disposed in order to promote fixing of the reflective mask 200 by an electrostatic chuck. As illustrated in FIG. 1, the conductive film 42 of the substrate with a conductive film 40 of the present embodiment includes an outermost layer 46 and a conductive layer 44.

### <<Outermost Layer 46>>

As illustrated in FIG. 1, the outermost layer 46 included in the conductive film 42 of the substrate with a conductive film 40 of the present embodiment is disposed on an outermost surface of the conductive film 42 on a side opposite to the substrate 10. By inclusion of the predetermined outermost layer 46 in the conductive film 42 of the substrate with a conductive film 40 of the present embodiment, it is possible to suppress hydrogen existing outside from being taken into the conductive film 42.

The outermost layer 46 contains a metal (M), boron (B), and oxygen (O).

The present inventors have found that a film stress of the conductive film 42 changes when hydrogen is taken into the conductive film 42 containing tantalum as a metal (M). Furthermore, the present inventors have found that also in a case of the conductive film 42 containing a metal (M) other than tantalum, the volume of the conductive film 42 changes when hydrogen is taken into the conductive film 42, and therefore a film stress of the conductive film 42 may change. By the change in film stress of the conductive film 42, a problem that a flatness of the reflective mask blank 100 changes occurs. Furthermore, a problem that positional deviation of a pattern of the reflective mask 200 occurs with a lapse of time after the reflective mask 200 is prepared occurs.

The present inventors have found that hydrogen taken into the conductive film 42 is hydrogen existing outside the reflective mask 200 in an EUV exposure environment. The present inventors have found that by inclusion of the predetermined outermost layer 46 in the conductive film 42 of the substrate with a conductive film 40 of the present embodiment, it is possible to suppress hydrogen existing outside the reflective mask 200 from being taken into the conductive film 42 of the reflective mask 200 in an EUV exposure environment, leading to the substrate with a conductive film 40 of the present embodiment. By manufacturing the reflective mask blank 100 and the reflective mask 200 using the substrate with a conductive film 40 of the present embodiment, it is possible to suppress hydrogen from being taken into the conductive film 42 of the reflective mask blank 100 and the reflective mask 200. Therefore, it is possible to suppress a change in film stress of the conductive film 42 of the reflective mask blank 100 and the reflective mask 200. That is, the substrate with a conductive film 40 of the present embodiment can suppress a change in flatness of the reflective mask blank 100 and the reflective mask 200. As a result, it is possible to suppress occurrence of positional deviation of a pattern of the reflective mask 200 with a lapse of time after the reflective mask 200 is prepared.

The metal (M) contained in the outermost layer 46 is preferably at least one selected from Ta, Cr, Pt, Au, Rh, Ru, Ir, and Hf. The metal (M) contained in the outermost layer 46 is more preferably at least one selected from Ta and Cr. When the metal (M) contained in the outermost layer 46 is a predetermined element, it is possible to more reliably suppress hydrogen existing outside from being taken into the conductive film 42.

In the substrate with a conductive film 40 of the present embodiment, the content of boron (B) in the outermost layer 46 is preferably 0.5 to 25 at %, and more preferably 1 to 15 at %. When the content of boron (B) in the outermost layer 46 is in a predetermined range, the function of suppressing incorporation of hydrogen by the outermost layer 46 can be further reliably achieved.

In addition, the content of the metal (M) in the outermost layer 46 is preferably 10 to 70 at %, and more preferably 20 to 60 at %. The content of O in the outermost layer 46 is preferably 20 to 80 at %, and more preferably 30 to 70 at %. Note that, according to the study of the present inventors, a film containing the metal (M), boron (B), and oxygen (O) (for example, a TaBO film or a TaBON film) has a higher function of suppressing incorporation of hydrogen than a film containing the metal (M) and oxygen (O) (for example, a TaO film). Therefore, by inclusion of boron (B) in the outermost layer 46, the function of suppressing incorporation of hydrogen by the conductive film 42 can be enhanced. A ratio between boron (B) and oxygen (O) in the outermost layer 46 is preferably B:O=1:20 to 1:70, and more preferably 1:30 to 1:60.

In order to more reliably suppress hydrogen existing outside from being taken into the conductive film 42, the material of the outermost layer 46 is preferably TaBO or TaBON.

When the material of the outermost layer 46 is TaBO, a composition of tantalum (Ta), boron (B), and oxygen (O) is preferably 15 to 60 at % for Ta, 0.5 to 25 at % for B, and 20 to 80 at % for O, and more preferably 25 to 50 at % for Ta, 1 to 15 at % for B, and 30 to 70 at % for O. Note that the material of the outermost layer 46 can contain an element other than Ta, B, and O within a range not affecting the effect of the present embodiment.

When the material of the outermost layer 46 is TaBON, a composition of tantalum (Ta), boron (B), oxygen (O), and nitrogen (N) is preferably 20 to 55 at % for Ta, 0.5 to 25 at % for B, 25 to 75 at % for O, and 0.5 to 40 at % for N, and more preferably 25 to 50 at % for Ta, 1 to 15 at % for B, 30 to 70 at % for O, and 1 to 30 at % for N. Note that the material of the outermost layer 46 can contain an element other than Ta, B, O, and N within a range not affecting the effect of the present embodiment.

When the material of the outermost layer 46 (TaBO or TaBON) has the above-described composition, it is possible to more preferably suppress hydrogen existing outside from being taken into the conductive film 42.

In the outermost layer 46, a B1s narrow spectrum obtained by analysis by X-ray photoelectron spectroscopy (XPS method) has a maximum peak at binding energy of 190 eV or more and 195 eV or less. In the XPS method, electrons of atoms contained in a substance are excited by an X-ray and emitted to the outside as photoelectrons. By measuring energy (binding energy) of photoelectrons emitted to the outside, an energy distribution (spectrum) of photoelectrons can be obtained.

The outermost layer 46 included in the conductive film 42 of the substrate with a conductive film 40 of the present embodiment contains boron (B). By detecting photoelectrons having binding energy in a range of 180 eV to 205 eV by the XPS method, a B1s narrow spectrum of boron (B) in the outermost layer 46 can be obtained. The present inventors have found that when the B1s narrow spectrum of the outermost layer 46 has a maximum peak at binding energy of 190 eV or more and 195 eV or less, hydrogen existing outside can be suppressed from being taken into the conductive film 42. The peak at binding energy of 190 eV or more and 195 eV or less in the B1s narrow spectrum is considered to be a peak due to a bond between B and O in the outermost layer 46. Therefore, when there are many bonds between B and O in the outermost layer 46, it is presumed that the hydrogen suppression effect of the outermost layer 46 is high.

In the substrate with a conductive film 40 of the present embodiment, in the outermost layer 46, a B1s narrow spectrum obtained by analysis by the X-ray photoelectron spectroscopy preferably has no peak at binding energy of 185 eV or more and less than 190 eV. The peak at binding energy of 185 eV or more and less than 190 eV in the B1s narrow spectrum is considered to be a peak due to a bond between B and M in the outermost layer 46. Therefore, when there are not many or no bonds between B and M in the outermost layer 46, it is presumed that the hydrogen suppression effect of the outermost layer 46 is high.

Note that it is known that energy (binding energy) of photoelectrons emitted to the outside in the XPS method varies depending on a film thickness and film formation conditions, and is not uniquely related to a composition. A specific example of an analysis method by the X-ray photoelectron spectroscopy (XPS method) will be described later.

In the substrate with a conductive film 40 of the present embodiment, the film thickness of the outermost layer 46 can be 2 nm to 30 nm, and can be 2 nm to 20 nm. In addition, the film thickness of the outermost layer 46 is preferably 2 nm to 10 nm, more preferably 3 nm to 8 nm, and still more preferably 4 nm to 6 nm. When the film thickness of the outermost layer 46 is within the predetermined range, the function of the conductive film 42 as an electrostatic chuck can be exhibited while the function of suppressing incorporation of hydrogen by the outermost layer 46 is further ensured.

### <<Conductive Layer 44>>

As illustrated in FIG. 1, the conductive layer 44 included in the conductive film 42 of the substrate with a conductive film 40 of the present embodiment is disposed between the outermost layer 46 and the substrate 10. By inclusion of the predetermined conductive layer 44 in the conductive film 42, the conductive film 42 can have a function of an electrostatic chuck for promoting fixing of the reflective mask 200.

The conductive layer 44 of the substrate with a conductive film 40 of the present embodiment preferably contains a metal (M) and boron (B). When the conductive layer 44 is made of a material containing boron, the conductive film 42 having wear resistance and chemical resistance can be obtained. In addition, the conductive layer 44 can further contain nitrogen (N).

The metal (M) contained in the conductive layer 44 is preferably at least one selected from Ta, Cr, Pt, Au, Rh, Ru, Ir, and Hf as in the case of the outermost layer 46. In addition, the metal (M) is more preferably at least one selected from Ta and Cr as in the case of the outermost layer 46. The metal (M) contained in the conductive layer 44 can be an element of a type different from the metal (M) contained in the outermost layer 46. Note that, in order to facilitate film formation of the conductive layer 44 and the outermost layer 46, the metal (M) contained in the conductive layer 44 is preferably the same type of element as the metal (M) contained in the outermost layer 46. When the conductive film 42 is made of a material containing a predetermined metal (M), an electrostatic chuck operates properly, and therefore appropriate sheet resistance can be obtained.

The content of the metal (M) in the conductive layer 44 is preferably 60 to 95 at %, and more preferably 70 to 90 at %. The content of boron (B) in the conductive layer 44 is preferably 2 to 40 at %, and more preferably 5 to 30 at %.

The metal (M) contained in the conductive layer 44 more preferably contains Ta. Specific examples of the material containing Ta for the conductive layer 44 include Ta, TaB, TaBO, TaBN, TaBON, TaO, TaON, TaN, and the like. TaB is preferably used as the material containing Ta for the conductive layer 44. When the conductive layer 44 is made of a material containing tantalum and boron, the conductive film 42 having wear resistance and chemical resistance can be obtained. For a similar reason, the total content of oxygen (O) and nitrogen (N) contained in the conductive layer 44 is preferably 30 at % or less, and more preferably 20 at % or less.

When the material of the conductive layer 44 is TaB, a composition of tantalum (Ta) and boron (B) is preferably 75 to 95 at % for Ta and 5 to 25 at % for B, and more preferably 80 to 90 at % for Ta and 10 to 20 at % for B. Note that the material of the conductive layer 44 can contain an element other than Ta and B within a range not affecting the effect of the present embodiment.

The composition of the conductive layer 44 is not necessarily the same in a film thickness direction. The conductive layer 44 can be a composition-gradient film whose composition changes in the film thickness direction. In addition, the conductive film 42 including the outermost layer 46 can also be a composition-gradient film whose composition changes in the film thickness direction.

In addition, the conductive layer 44 may be a plurality of layers of two or more layers. In this case, the conductive layer 44 can include an upper layer on the outermost layer 46 side and a lower layer other than the upper layer. The lower layer can have a similar configuration to the conductive layer 44 described above. The upper layer can contain a metal (M) and nitrogen (N). In addition, the metal (M) in the upper layer is preferably the same metal as the metal in at least one of the lower layer and the outermost layer 46 from a viewpoint of continuous film formation of the conductive layer 44. In addition, the upper layer preferably further contains boron (B). Specific examples of the material of the upper layer include TaBN and TaBON.

A composition when the material of the upper layer is TaBN is preferably 15 to 90 at % for Ta, 0.5 to 25 at % for B, and 5 to 50 at % for N, and more preferably 25 to 80 at % for Ta, 1 to 15 at % for B, and 10 to 40 at % for N. A composition when the material of the upper layer is TaBON can be similar to that of the outermost layer 46 described above. In addition, the film thickness of the upper layer is preferably 1 to 15 nm, and more preferably 2 to 10 nm.

The film thickness of the conductive layer 44 can be appropriately controlled within a range in which appropriate sheet resistance can be obtained. The film thickness of the conductive layer 44 is preferably 10 nm or more, and more preferably 20 nm or more. In addition, in order to reduce surface roughness of the conductive film 42, the film thickness of the conductive layer 44 is preferably 200 nm or less, and more preferably 100 nm or less.

In the conductive layer 44 of the substrate with a conductive film 40 of the present embodiment, a B1s narrow spectrum obtained by analysis by the X-ray photoelectron spectroscopy (XPS method) preferably has a maximum peak at binding energy of 185 eV or more and less than 190 eV. The peak at binding energy of 185 eV or more and less than 190 eV in the B1s narrow spectrum is considered to be a peak due to a bond between B and M in the conductive layer 44. When there are many bonds between B and M in the conductive layer 44, even if the thin outermost layer 46 exists on a surface of the conductive film 42, a frictional force (electrostatic friction coefficient) between the surface of the conductive film 42 and an adsorption holding surface of an electrostatic chuck of an exposure apparatus can be increased. Therefore, it is possible to suppress positional deviation of the reflective mask 200 at the time of pattern transfer.

The above-described analysis by the X-ray photoelectron spectroscopy (XPS method) can be performed as follows.

In the analysis of the conductive film 42 by the X-ray photoelectron spectroscopy (XPS method), two types of analysis including surface analysis and internal analysis can be performed. In the surface analysis, by emitting an X-ray from an X-ray source toward a surface of the substrate with a conductive film 40 (conductive film 42), an energy distribution of photoelectrons emitted from the outermost layer 46 of the conductive film 42 can be measured. In the internal analysis, by digging the conductive film 42 by Ar gas sputtering to such an extent that the conductive layer 44 can be analyzed (for example, about 10 nm), and irradiating a surface of the conductive film 42 (conductive layer 44) in the dug region with an X-ray, an energy distribution of photoelectrons emitted from the conductive layer 44 of the conductive film 42 can be measured. The digging depth for the internal analysis can be determined according to the film thickness of the outermost layer 46. For example, in a case where the film thickness of the outermost layer 46 is 20 nm, the digging depth for the internal analysis can be about 30 nm. The measurement for analysis by the X-ray photoelectron spectroscopy (XPS method) is preferably performed under the following measurement conditions.

### (Measurement Conditions of XPS Method)

X-ray source: AlKα ray (1486.6 eV)
Photoelectron detection region: diameter 200 μm
Measurement range of photoelectron binding energy: 180 eV to 205 eV
Extraction angle of photoelectron detection: 45 degrees (detection depth: about 4 to 5 nm)
Step size in measurement: 0.25 eV

Since the detection depth is about 4 to 5 nm under the above-described measurement conditions of the XPS method, most of photoelectrons analyzed by the XPS method are considered to be photoelectrons emitted from the outermost layer 46 in the surface analysis. Therefore, information obtained by the surface analysis can be considered to be information of the outermost layer 46. In addition, in the internal analysis in which the conductive film 42 is dug by, for example, about 10 nm by Ar gas sputtering, most of photoelectrons analyzed by the XPS method are considered to be photoelectrons emitted from the conductive layer 44. Therefore, information obtained by the internal analysis can be considered to be information of the conductive layer 44.

In the present specification, the peak obtained by analysis by the X-ray photoelectron spectroscopy (XPS method) is a peak when a spectrum of binding energy of photoelectrons measured as described above (signal intensity with respect to binding energy in a predetermined range) is illustrated, and a signal intensity of a peak when a background is subtracted from a measured spectrum can be twice or more the magnitude of background noise (the width of vibration of signal intensity of the noise) in the vicinity of the peak. The binding energy of the peak can be binding energy that indicates a maximum value of a peak when a background is subtracted from a measured spectrum. In addition, the signal intensity and the binding energy of the peak can be determined using a known curve fitting method.

In order for an electrostatic chuck to operate properly, sheet resistance of the conductive film 42 can be preferably 200Ω/□ (square) or less, more preferably 100Ω/□ or less, still more preferably 75Ω/□ or less, and particularly preferably 50Ω/□ or less. For the sheet resistance, the conductive film 42 having appropriate sheet resistance can be obtained by adjusting the composition and the film thickness of the conductive film 42 (particularly, the conductive layer 44).

The film thickness of the conductive film 42 can be appropriately controlled within a range in which the above-described sheet resistance can be obtained. The film thickness of the conductive film 42 is preferably 10 nm or more, and more preferably 20 nm or more. In addition, the film thickness of the conductive film 42 is preferably 210 nm or less, and more preferably 100 nm or less from a viewpoint of reducing surface roughness.

As a method for forming the conductive film 42 (conductive layer 44 and outermost layer 46), it is preferable to form a film by sputtering using a sputtering target containing a metal which is a material of the conductive film 42. Specifically, it is preferable to rotate the substrate 10 on a horizontal plane with a film formation surface of the substrate 10 for forming the conductive film 42 facing upward. In addition, the substrate 10 is preferably disposed at a position where a central axis of the substrate 10 and a straight line passing through the center of a sputtering target and parallel to the central axis of the substrate 10 are shifted from each other. In addition, it is preferable to form the conductive film 42 (conductive layer 44 and outermost layer 46) by sputtering a sputtering target facing a film formation surface at a predetermined angle. The predetermined angle is preferably an angle at which an inclination angle of the sputtering target is 5 degrees or more and 30 degrees or less. In addition, a gas pressure during sputtering film formation is preferably 0.03 Pa or more and 0.5 Pa or less. By forming the conductive film 42 by such a method, the desired conductive film 42 (conductive layer 44 and outermost layer 46) can be obtained.

When a rare gas is used as a gas used for sputtering film formation, it is considered that a real contact area of a surface of the conductive film 42 can be increased by using krypton (Kr) and xenon (Xe) each having an atomic weight larger than that of argon (Ar), and as a result, a static friction coefficient of the conductive film 42 can be increased. As a result, a frictional force (electrostatic friction coefficient) between a surface of the conductive film 42 and an adsorption holding surface of an electrostatic chuck of an exposure apparatus can be increased, and positional deviation of the reflective mask 200 at the time of pattern transfer can be suppressed.

### <<Other Thin Film>>

The conductive film 42 of the substrate with a conductive film 40 of the present embodiment can include a layer (thin film) other than the conductive layer 44 and the outermost layer 46.

The substrate with a conductive film 40, the substrate with a multilayer reflective film 20, and the reflective mask blank 100 of the present embodiment preferably each include a hydrogen intrusion suppressing film as an intermediate layer for suppressing intrusion of hydrogen from the substrate 10 (glass substrate) into the conductive layer 44 between a glass substrate which is the substrate 10 and the conductive layer 44. The presence of the hydrogen intrusion suppressing film can suppress hydrogen from being taken into the conductive layer 44, and can suppress an increase in a compressive stress of the conductive layer 44.

A material of the hydrogen intrusion suppressing film may be any type of material as long as the material hardly transmits hydrogen and can suppress intrusion of hydrogen from the substrate 10 (glass substrate) into the conductive film 42. The hydrogen intrusion suppressing film can be a thin film having the same characteristics as the above-described outermost layer 46. That is, similarly to the outermost layer 46, the hydrogen intrusion suppressing film can be a film in which a B1s narrow spectrum obtained by analysis by the X-ray photoelectron spectroscopy has a maximum peak at binding energy of 190 eV or more and 195 eV or less. In addition, the hydrogen intrusion suppressing film can be a thin film having the same material and/or the same composition as the outermost layer 46.

In order to reliably suppress intrusion of hydrogen into the conductive film 42, the material of the hydrogen intrusion suppressing film is preferably a material containing tantalum and oxygen. Preferable examples of the material of the hydrogen intrusion suppressing film include TaO, TaON, TaBO, and TaBON. The material of the hydrogen intrusion suppressing film is more preferably a material selected from TaO, TaON, TaBO, and TaBON, and having an oxygen content of 50 at % or more. The hydrogen intrusion suppressing film can be a single layer made of these materials, or may be a film made of a plurality of layers or a composition-gradient film.

The thickness of the hydrogen intrusion suppressing film is preferably 1 nm or more, more preferably 5 nm or more, and still more preferably 10 nm or more. When the thickness of the hydrogen intrusion suppressing film is less than 1 nm, the hydrogen intrusion suppressing film is too thin and an effect of preventing hydrogen intrusion cannot be expected. In addition, when the thickness of the hydrogen intrusion suppressing film is less than 1 nm, it is not easy to form a hydrogen intrusion suppressing film having a substantially uniform film thickness and a substantially uniform film composition on a main surface of the substrate 10 (glass substrate) even by a sputtering method.

In order to prevent the conductive film 42 from coming into contact with the substrate 10 (glass substrate), the hydrogen intrusion suppressing film is preferably formed in the same region as a formation region of the conductive film 42 on the main surface of the substrate 10 (glass substrate) or in a region wider than the formation region of the conductive film 42.

[Substrate with a Multilayer Reflective Film 20]

Next, the substrate with a multilayer reflective film 20 of the present embodiment will be described. FIGS. 2 and 3 illustrate schematic cross-sectional views of an example of the substrate with a multilayer reflective film 20. The above-described conductive film 42 is disposed on a second main surface (back surface) of the substrate with a multilayer reflective film 20 illustrated in FIGS. 2 and 3. The substrate with a multilayer reflective film 20 including the conductive film 42 is one type of the substrate with a conductive film 40 of the present embodiment.

### <Multilayer Reflective Film 21>

The substrate with a multilayer reflective film 20 of the present embodiment includes the multilayer reflective film 21 on a first main surface of the substrate 10. The multilayer reflective film 21 imparts a function of reflecting EUV light in the reflective mask 200. The multilayer reflective film 21 is a multilayer film in which layers mainly containing elements having different refractive indices are periodically layered.

In general, as the multilayer reflective film 21, a multilayer film is used in which a thin film (high refractive index layer) of a light element that is a high refractive index material or a compound of the light element and a thin film (low refractive index layer) of a heavy element that is a low refractive index material or a compound of the heavy element are alternately layered for about 40 to 60 periods.

When a stack of a high refractive index layer and a low refractive index layer in which the high refractive index layer and the low refractive index layer are layered in this order from the substrate 10 side is counted as one period, the multilayer film used as the multilayer reflective film 21 can have a structure formed by building up the stack for a plurality of periods. In addition, when a stack of a low refractive index layer and a high refractive index layer in which the low refractive index layer and the high refractive index layer are layered in this order from the substrate 10 side is counted as one period, the multilayer film can be formed by building up the stack for a plurality of periods. Note that an outermost layer of the multilayer reflective film 21, that is, an uppermost layer of the multilayer reflective film 21 opposite to the substrate 10 side is preferably a high refractive index layer. In the above-described multilayer film, when a stack of a high refractive index layer and a low refractive index layer in which the high refractive index layer and the low refractive index layer are layered in this order from the substrate 10 side is counted as one period and the stack is built up for a plurality of periods, the uppermost layer is the low refractive index layer. In this case, when a low refractive index layer constitutes the outermost surface of the multilayer reflective film 21, the low refractive index layer is easily oxidized and the reflectance of the reflective mask 200 is reduced. Therefore, it is preferable to further form a high refractive index layer on the low refractive index layer that is the uppermost layer to form the multilayer reflective film 21. Meanwhile, in the above-described multilayer film, when a stack of a low refractive index layer and a high refractive index layer in which the low refractive index layer and the high refractive index layer are layered in this order from the substrate 10 side is counted as one period and the stack is built up for a plurality of periods, the uppermost layer is the high refractive index layer. Therefore, in this case, it is not necessary to further form a high refractive index layer.

As the high refractive index layer, a layer containing silicon (Si) can be used. As a material containing Si, a Si compound containing Si and boron (B), carbon (C), nitrogen (N), oxygen (O), and/or hydrogen (H) can be used in addition to a Si simple substance. By using the high refractive index layer containing Si, the reflective mask 200 having an excellent reflectance for EUV light can be obtained. In addition, as the low refractive index layer, a metal simple substance selected from molybdenum (Mo), ruthenium (Ru), rhodium (Rh), and platinum (Pt), or an alloy thereof can be used. In addition, to these metal simple substances or alloys, boron (B), carbon (C), nitrogen (N), oxygen (O), and/or hydrogen (H) may be added. In the substrate with a multilayer reflective film 20 of the present embodiment, the low refractive index layer is preferably a molybdenum (Mo) layer, and the high refractive index layer is preferably a silicon (Si) layer. For example, as the multilayer reflective film 21 for reflecting EUV light having a wavelength of 13 nm to 14 nm (for example, a wavelength of 13.5 nm), a Mo/Si periodic layered film in which a Mo layer and a Si layer are alternately layered for about 40 to 60 periods can be preferably used. In the substrate with a multilayer reflective film 20 of the present embodiment, the low refractive index layer is preferably a ruthenium (Ru) layer, and the high refractive index layer is preferably a silicon (Si) layer. For example, as the multilayer reflective film 21 for reflecting EUV light having a wavelength of 13 nm to 14 nm (for example, a wavelength of 13.5 nm), a Ru/Si periodic layered film in which a Ru layer and a Si layer are alternately layered for about 30 to 40 periods can be preferably used.

A reflectance of the multilayer reflective film 21 alone is usually 65% or more, and an upper limit thereof is usually 73%. Note that the film thickness and period of each constituent layer of the multilayer reflective film 21 can be appropriately selected depending on an exposure wavelength. Specifically, the film thickness and period of each constituent layer of the multilayer reflective film 21 can be selected so as to satisfy the Bragg reflection law. In the multilayer reflective film 21, there are a plurality of high refractive index layers and a plurality of low refractive index layers, but the film thickness does not need to be the same between the high refractive index layers and between the low refractive index layers.

A method for forming the multilayer reflective film 21 is publicly known in this technical field. Each layer of the multilayer reflective film 21 can be formed by, for example, an ion beam sputtering method or a magnetron sputtering method. In the case of the above-described Mo/Si periodic multilayer film, a Si film having a thickness of about 4 nm is first formed on the substrate 10 using a Si target, for example, by an ion beam sputtering method. Then, a Mo film having a thickness of about 3 nm is formed using a Mo target. This stack is counted as one period, and the stack is built up for 40 to 60 periods to form the multilayer reflective film 21 (the uppermost layer on the outermost surface is a Si film). Note that, in the case of 60 periods, the number of steps is larger than the number of steps in the case of 40 periods, but the reflectance for EUV light can be increased.

### <Protective Film 22>

The substrate with a multilayer reflective film 20 (substrate with a conductive film 40) of the present embodiment preferably further includes the protective film 22 disposed in contact with a surface of the multilayer reflective film 21 on a side opposite to the substrate 10.

On the multilayer reflective film 21 formed as described above, the protective film 22 (see FIG. 3) can be formed for protecting the multilayer reflective film 21 from dry etching or wet cleaning in a process of manufacturing the reflective mask 200. As described above, the mode including the multilayer reflective film 21 and the protective film 22 on the substrate 10 can also be the substrate with a multilayer reflective film 20 (substrate with a conductive film 40) of the present embodiment.

The protective film 22 is formed on the multilayer reflective film 21 in the substrate with a multilayer reflective film 20 of the present embodiment, whereby it is possible to suppress damage to a surface of the multilayer reflective film 21 when the reflective mask 200 (an EUV mask) is manufactured using the substrate with a multilayer reflective film 20. Therefore, a reflectance characteristic of the obtained reflective mask 200 for EUV light is improved.

Note that as a material of the protective film 22, for example, a material such as Ru, Rh, Ru—(Nb, Rh, Zr, Y, B, Ti, La, or Mo), Si—(Ru, Rh, Cr, or B), Si, Zr, Nb, La, or B can be used. Among these materials, when a material containing ruthenium (Ru) is applied, a reflectance characteristic of the multilayer reflective film 21 is further improved. Specifically, the material of the protective film 22 is preferably Ru or Ru—(Nb, Rh, Zr, Y, B, Ti, La, or Mo). Such a protective film 22 is particularly effective in a case where the absorber film 24 is made of a Ta-based material and patterned by dry etching with a Cl-based gas.

In the substrate with a multilayer reflective film 20 (substrate with a conductive film 40) of the present embodiment, an underlayer may be formed between the substrate 10 and the multilayer reflective film 21. The underlayer can be formed for the purpose of improving smoothness of a main surface of the substrate 10, reducing defects, enhancing a reflectance of the multilayer reflective film 21, and correcting a stress of the multilayer reflective film 21.

### [Reflective Mask Blank 100]

Next, the reflective mask blank 100 of the present embodiment will be described. FIG. 4 is a schematic cross-sectional view illustrating an example of the reflective mask blank 100 of the present embodiment. The reflective mask blank 100 of the present embodiment has a structure in which the absorber film 24 is formed on the multilayer reflective film 21 or on the protective film 22 of the above-described substrate with a multilayer reflective film 20. The above-described conductive film 42 is disposed on a second main surface (back surface) of the substrate 10 of the reflective mask blank 100 illustrated in FIG. 4.

### <Absorber Film 24>

The absorber film 24 of the reflective mask blank 100 of the present embodiment is formed on the protective film 22. A basic function of the absorber film 24 is to absorb EUV light. The absorber film 24 may be the absorber film 24 for the purpose of absorbing EUV light, or may be the absorber film 24 having a phase shift function in consideration of a phase difference of EUV light. The absorber film 24 having a phase shift function absorbs EUV light and reflects a part of the EUV light to shift a phase. That is, in the reflective mask 200 in which the absorber film 24 having a phase shift function is patterned, in a portion where the absorber film 24 is formed, a part of light is reflected at a level that does not adversely affect pattern transfer while EUV light is absorbed and attenuated. In addition, in a region (field portion) where the absorber film 24 is not formed, EUV light is reflected by the multilayer reflective film 21 via the protective film 22. Therefore, there is a desired phase difference between reflected light from the absorber film 24 having a phase shift function and reflected light from the field portion. The absorber film 24 having a phase shift function is formed such that a phase difference between reflected light from the absorber film 24 and reflected light from the multilayer reflective film 21 is 170 to 260 degrees. Beams of the light having a reversed phase difference interfere with each other at a pattern edge portion, and an image contrast of a projected optical image is thereby improved. As the image contrast is improved, resolution is increased, and various exposure-related margins such as an exposure margin and a focus margin can be increased.

The absorber film 24 may be a single-layer thin film (single layer film) or a multilayer film including a plurality of films (for example, a lower absorber film and an upper absorber film). In a case of a single layer film, the number of steps at the time of manufacturing a mask blank can be reduced and production efficiency is increased. In a case of a multilayer film, an optical constant and a film thickness of an upper absorber film can be appropriately set such that the upper absorber film serves as an antireflection film at the time of mask pattern defect inspection using light. This improves inspection sensitivity at the time of mask pattern defect inspection using light. In addition, when a thin film containing oxygen (O), nitrogen (N), and the like that improve oxidation resistance is used as the upper absorber film, temporal stability is improved. As described above, by forming the absorber film 24 into a multilayer film, various functions can be added to the absorber film 24. When the absorber film 24 is the absorber film 24 having a phase shift function, by forming the absorber film 24 into a multilayer film, a range of adjustment on an optical surface can be increased, and therefore a desired reflectance can be easily obtained.

A material of the absorber film 24 is not particularly limited as long as the material has a function of absorbing EUV light, can be processed by etching or the like (preferably, can be etched by dry etching with a chlorine (Cl)-based gas and/or a fluorine (F)-based gas), and has a high etching selective ratio to the protective film 22. As a material having such a function, at least one metal selected from palladium (Pd), silver (Ag), platinum (Pt), gold (Au), iridium (Ir), tungsten (W), chromium (Cr), cobalt (Co), manganese (Mn), tin (Sn), tantalum (Ta), vanadium (V), nickel (Ni), hafnium (Hf), iron (Fe), copper (Cu), tellurium (Te), zinc (Zn), magnesium (Mg), germanium (Ge), aluminum (Al), rhodium (Rh), ruthenium (Ru), molybdenum (Mo), niobium (Nb), titanium (Ti), zirconium (Zr), yttrium (Y), and silicon (Si), an alloy containing two or more metals selected therefrom, or a compound thereof can be preferably used. The compound may further contain oxygen (O), nitrogen (N), carbon (C), and/or boron (B) in the metal or alloy.

The absorber film 24 can be formed by a magnetron sputtering method such as a DC sputtering method or an RF sputtering method. For example, the absorber film 24 such as a tantalum compound can be formed by a reactive sputtering method using a target containing tantalum and boron and using an argon gas containing oxygen or nitrogen.

In addition, a crystalline state of the absorber film 24 is preferably an amorphous or microcrystalline structure from a viewpoint of smoothness and flatness. If a surface of the absorber film 24 is not smooth or flat, the absorber pattern 24a may have a large edge roughness and a poor pattern dimensional accuracy. The absorber film 24 has a surface roughness of preferably 0.5 nm or less, more preferably 0.4 nm or less, still more preferably 0.3 nm or less in terms of root mean square roughness (Rms).

### <Etching Mask Film 25>

FIG. 5 is a schematic cross-sectional view illustrating another example of the reflective mask blank 100 of the present embodiment. The reflective mask blank 100 illustrated in FIG. 5 can include an etching mask film 25 on the absorber film 24. As a material of the etching mask film 25, a material having a high etching selective ratio (etching rate of absorber film 24/etching rate of etching mask film 25) of the absorber film 24 to the etching mask film 25 is preferably used. The etching selective ratio of the absorber film 24 to the etching mask film 25 is preferably 1.5 or more, and more preferably 3 or more.

The reflective mask blank 100 of the present embodiment preferably includes the etching mask film 25 on the absorber film 24.

As a material of the etching mask film 25, chromium or a chromium compound is preferably used. Examples of the chromium compound include a material containing Cr and at least one element selected from N, O, C, and H. The etching mask film 25 more preferably contains CrN, CrO, CrC, CrON, CrOC, CrCN, or CrOCN, and is still more preferably a CrO-based film containing chromium and oxygen (CrO film, CrON film, CrOC film, or CrOCN film).

As the material of the etching mask film 25, tantalum or a tantalum compound is preferably used. Examples of the tantalum compound include a material containing Ta and at least one element selected from N, O, B, and H. The etching mask film 25 more preferably contains TaN, TaO, TaON, TaBN, TaBO, or TaBON.

As the material of the etching mask film 25, silicon or a silicon compound is preferably used. Examples of the silicon compound include a material containing Si and at least one element selected from N, O, C, and H, a metallic silicon containing a metal in addition to silicon or a silicon compound (metal silicide), a metal silicon compound (metal silicide compound), and the like. Examples of the metal silicon compound include a material containing a metal, Si, and at least one element selected from N, O, C, and H.

The film thickness of the etching mask film 25 is preferably 3 nm or more in order to accurately form a pattern on the absorber film 24. In addition, the film thickness of the etching mask film 25 is preferably 15 nm or less in order to reduce the film thickness of a resist film 32.

### [Reflective Mask 200]

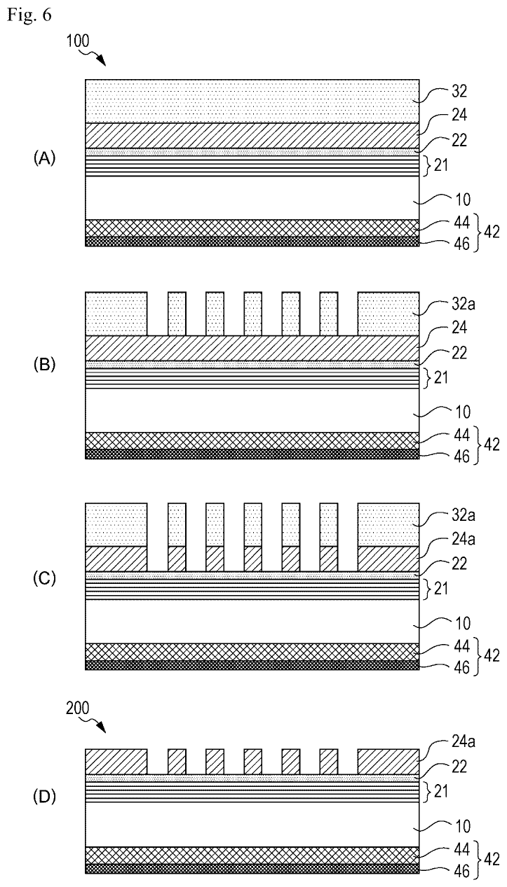

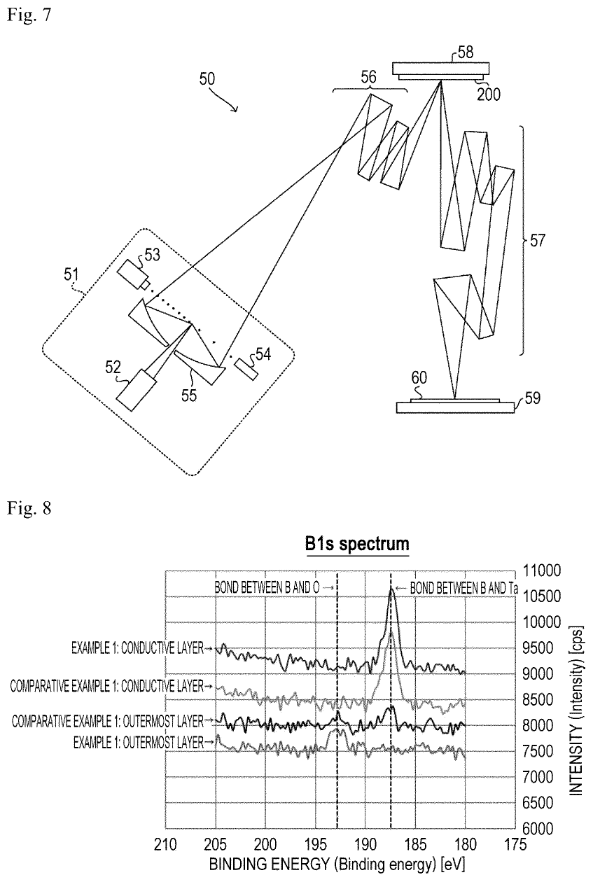

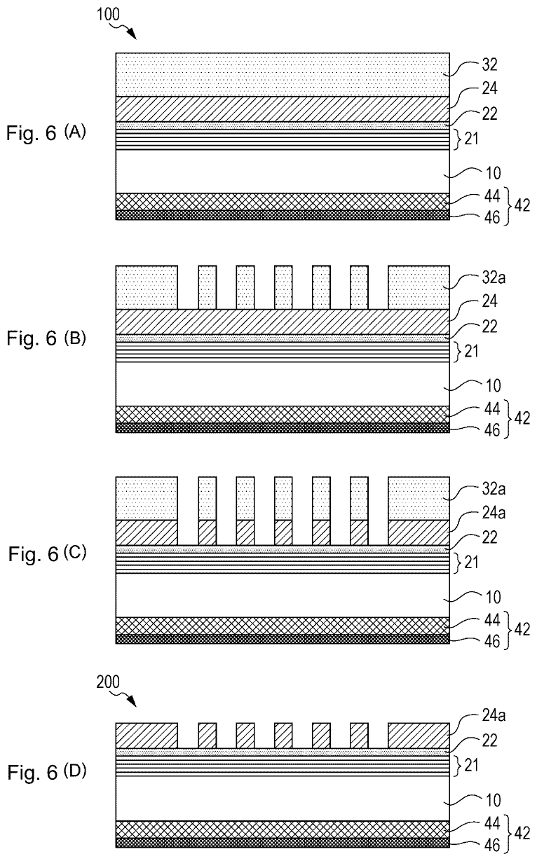

As illustrated in FIG. 6(D), the reflective mask 200 of the present embodiment has the absorber pattern 24a obtained by patterning the absorber film 24 of the above-described reflective mask blank 100. The reflective mask 200 illustrated in FIG. 6(D) includes the above-described conductive film 42 on a second main surface (back surface) of the substrate 10.

FIGS. 6(A) to 6(D) are schematic cross-sectional views illustrating an example of a method for manufacturing the reflective mask 200. Using the above-described reflective mask blank 100 of the present embodiment, the reflective mask 200 of the present embodiment can be manufactured. Hereinafter, an example of a method for manufacturing the reflective mask 200 will be described.

First, the reflective mask blank 100 including the substrate 10, the multilayer reflective film 21 formed on the substrate 10, the protective film 22 formed on the multilayer reflective film 21, and the absorber film 24 formed on the protective film 22 is prepared. Next, the resist film 32 is formed on the absorber film 24 to obtain the reflective mask blank 100 with the resist film 32 (FIG. 6(A)). A pattern is drawn on the resist film 32 with an electron beam drawing device, and then the resulting product is subjected to a development and rinse step to form a resist pattern 32a (FIG. 6(B)).

The absorber film 24 is dry-etched using the resist pattern 32a as a mask. As a result, a portion not covered with the resist pattern 32a in the absorber film 24 is etched to form the absorber pattern 24a (FIG. 6(C)).

As an etching gas for the absorber film 24, a fluorine-based gas and/or a chlorine-based gas can be used. As the fluorine-based gas, CF₄, CHF₃, C₂F₆, C₃F₆, C₄F₆, C₄F₈, CH₂F₂, CH₃F, C₃F₈, SF₆, F₂, and the like can be used. As the chlorine-based gas, Cl₂, SiCl₄, CHCl₃, CCL, BCl₃, or the like can be used. In addition, a mixed gas containing a fluorine-based gas and/or a chlorine-based gas and O₂ at a predetermined ratio can be used. These etching gases can each further contain an inert gas such as He and/or Ar, if necessary.

After the absorber pattern 24a is formed, the resist pattern 32a is removed with a resist peeling liquid. After the resist pattern 32a is removed, the resulting product is subjected to a wet cleaning step using an acidic or alkaline aqueous solution to obtain the reflective mask 200 of the present embodiment (FIG. 6(D)).

Note that, when the reflective mask blank 100 in which the etching mask film 25 is formed on the absorber film 24 is used, a step of forming a pattern (etching mask pattern) on the etching mask film 25 using the resist pattern 32a as a mask and then forming a pattern on the absorber film 24 using the etching mask pattern as a mask is added.

The reflective mask 200 thus obtained has a structure in which the multilayer reflective film 21, the protective film 22, and the absorber pattern 24a are layered on the substrate 10.

A region (reflection region) where the multilayer reflective film 21 covered with the protective film 22 is exposed has a function of reflecting EUV light. A region where the multilayer reflective film 21 and the protective film 22 are covered with the absorber pattern 24a has a function of absorbing EUV light. By using the reflective mask 200 of the present embodiment, a reflection region having a high reflectance for EUV light can be obtained, and therefore a finer pattern can be transferred onto a transferred object in EUV lithography.

The reflective mask 200 of the present embodiment includes the above-described conductive film 42 on a second main surface (back surface) of the substrate 10. By inclusion of the predetermined conductive film 42 in the reflective mask 200 of the present embodiment, it is possible to suppress hydrogen existing outside the reflective mask 200 from being taken into the conductive film 42 of the reflective mask 200 in an EUV exposure environment. Therefore, the reflective mask 200 of the present embodiment can suppress a change in flatness. In addition, by using the reflective mask 200 of the present embodiment, it is possible to suppress occurrence of positional deviation of a pattern of the reflective mask 200 with a lapse of time after the reflective mask 200 is prepared.

### [Method for Manufacturing a Semiconductor Device]

A method for manufacturing a semiconductor device of the present embodiment includes a step of performing a lithography process using an exposure apparatus using the above-described reflective mask 200 to form a transfer pattern on a transferred object.

A transfer pattern can be formed on a semiconductor substrate 60 (transferred object) by lithography using the reflective mask 200 of the present embodiment. This transfer pattern has a shape obtained by transferring a pattern of the reflective mask 200. By forming a transfer pattern on the semiconductor substrate 60 with the reflective mask 200, a semiconductor device can be manufactured.

According to the present embodiment, a semiconductor device can be manufactured using the reflective mask 200 capable of suppressing occurrence of positional deviation of a pattern. Therefore, by using the reflective mask 200 of the present embodiment, it is possible to increase density and accuracy of a semiconductor device.

A method for transferring a pattern onto the semiconductor substrate with resist 60 using EUV light will be described with reference to FIG. 7.

FIG. 7 illustrates a schematic configuration of an EUV exposure apparatus 50 that is an apparatus for transferring a transfer pattern onto a resist film formed on the semiconductor substrate 60. In the EUV exposure apparatus 50, an EUV light generation unit 51, an irradiation optical system 56, a reticle stage 58, a projection optical system 57, and a wafer stage 59 are precisely arranged along an optical path axis of EUV light. A container of the EUV exposure apparatus 50 is filled with a hydrogen gas.

The EUV light generation unit 51 includes a laser light source 52, a tin droplet generation unit 53, a catching unit 54, and a collector 55. When a tin droplet emitted from the tin droplet generation unit 53 is irradiated with a high-power carbon dioxide laser from the laser light source 52, tin in a droplet state is turned into plasma to generate EUV light. The generated EUV light is collected by the collector 55, passes through the irradiation optical system 56, and enters the reflective mask 200 set on the reticle stage 58. The EUV light generation unit 51 generates, for example, EUV light having a wavelength of 13.53 nm.

EUV light reflected by the reflective mask 200 is usually reduced to about ¼ of pattern image light by the projection optical system 57 and projected on the semiconductor substrate 60 (transferred substrate). As a result, a given circuit pattern is transferred onto the resist film on the semiconductor substrate 60. By developing the resist film that has been subjected to exposure, a resist pattern can be formed on the semiconductor substrate 60. By etching the semiconductor substrate 60 using the resist pattern as a mask, an integrated circuit pattern can be formed on the semiconductor substrate 60. A semiconductor device is manufactured through such a step and other necessary steps.

By using the reflective mask 200 manufactured using the substrate with a conductive film 40 of the present embodiment, it is possible to suppress hydrogen existing outside the reflective mask 200 from being taken into the conductive film 42 of the reflective mask 200 in an EUV exposure environment. Therefore, a change in flatness of the reflective mask 200 can be suppressed. Therefore, by using the reflective mask 200 manufactured using the substrate with a conductive film 40 of the present embodiment, a highly accurate semiconductor device can be manufactured.

### Examples

Hereinafter, an example in which the substrate with a conductive film 40, the substrate with a multilayer reflective film 20, the reflective mask blank 100, and the reflective mask 200 of the present embodiment are manufactured will be described as Example.

First, the conductive film 42 was formed as described below on a second main surface (back surface) of the substrate 10 for EUV exposure to manufacture the substrates with a conductive film 40 in each of Examples 1 and 2 and Comparative Examples 1 and 2.

### <Preparation of Substrate 10>

The substrate 10 used for manufacturing the substrate with a conductive film 40 in each of Examples 1 and 2 and Comparative Examples 1 and 2 was manufactured as follows.

A SiO₂—TiO₂-based glass substrate that is a low thermal expansion glass substrate having a 6025 size (about 152 mm×about 152 mm×6.35 mm) and having polished both main surfaces that are a first main surface and a second main surface was prepared. The main surfaces of the substrate 10 were subjected to polishing including a rough polishing step, a precision polishing step, a local processing step, and a touch polishing step such that the main surfaces were flat and smooth.

### <Preparation of Conductive Film 42>

The conductive film 42 (conductive layer 44 and outermost layer 46) was formed in the following manner on a second main surface of the substrate 10 in each of Examples 1 and 2 and Comparative Examples 1 and 2 described above.

First, the conductive layer 44 of the conductive film 42 in each of Examples 1 and 2 and Comparative Examples 1 and 2 was formed. The conductive layer 44 was formed by performing sputtering (or reactive sputtering) in a Xe gas atmosphere with a TaB target facing a back surface (second main surface) of the substrate 10. By adjusting a film formation time of the conductive layer 44, the film thickness of the conductive layer 44 was set to the film thickness presented in Table 1. A composition ratio of the conductive layer 44 analyzed by X-ray photoelectron spectroscopy (XPS method) under measurement conditions described later was Ta:B=80:20 in each of Examples 1 and 2 and Comparative Examples 1 and 2.

Next, the outermost layer 46 of the conductive film 42 in each of Examples 1 and 2 and Comparative Example 2 was formed. The outermost layer 46 was formed by performing sputtering (or reactive sputtering) with the target presented in Table 2 facing a back surface (second main surface) of the substrate 10. By adjusting a film formation time of the outermost layer 46, the film thickness of the outermost layer 46 was set to the film thickness presented in Table 1. A composition ratio (at %) of the outermost layer 46 analyzed by X-ray photoelectron spectroscopy (XPS method) under measurement conditions described later is presented in Table 2.

Note that, in the conductive film 42 of Comparative Example 1, only the conductive layer 44 was formed, and the outermost layer 46 was not formed. However, it is considered that a natural oxide film was formed on a surface of the conductive layer 44 of Comparative Example 1. In the present specification, the natural oxide film on the surface of the conductive layer 44 of Comparative Example 1 is assumed to be a thin film corresponding to the outermost layer 46.

In this way, the substrate with a conductive film 40 having the structure illustrated in FIG. 1 was prepared.

### <Measurement by X-Ray Photoelectron Spectroscopy (XPS Method)>

The conductive film 42 of the substrate with a conductive film 40 in each of Examples 1 and 2 and Comparative Examples 1 and 2 was analyzed by X-ray photoelectron spectroscopy (XPS method). Specifically, by measuring energy (binding energy) in a range of 180 eV to 205 eV of photoelectrons excited by an X-ray with which the conductive film 42 of the substrate with a conductive film 40 in each of Examples 1 and 2 and Comparative Examples 1 and 2 was irradiated and emitted to the outside by the XPS method, an energy distribution of photoelectrons (B1s narrow spectrum) was obtained.

In the analysis of the conductive film 42 by the X-ray photoelectron spectroscopy (XPS method), two types of analysis including surface analysis and internal analysis were performed. In the surface analysis, by emitting an X-ray from an X-ray source toward a surface of the conductive film 42 of the substrate with a conductive film 40, an energy distribution of photoelectrons emitted from the outermost layer 46 of the conductive film 42 was measured. In the internal analysis, by digging the conductive film 42 by Ar gas sputtering by about 10 nm, irradiating a surface (outermost layer 46) of the conductive film 42 in the dug region with an X-ray, and measuring an energy distribution of photoelectrons emitted from the conductive film 42, the conductive layer 44 of the conductive film 42 was analyzed. Measurement conditions of analysis by the X-ray photoelectron spectroscopy are as follows.
X-ray source: AlK_{α} ray (1486.6 eV)
Photoelectron detection region: diameter 200 μm
Measurement range of photoelectron binding energy: 180 eV to 205 eV
Extraction angle of photoelectron detection: 45 degrees (detection depth: about 4 to 5 nm)
Step size in measurement: 0.25 eV

A detection depth by the XPS method is about 4 to 5 nm. Therefore, in the above-described surface analysis by the XPS method, information on the outermost layer 46 can be obtained. In the above-described internal analysis by the XPS method, information on the conductive film 42 can be obtained.

FIG. 8 illustrates B1s narrow spectra of the conductive layer 44 and the outermost layer 46 of the conductive film 42 of the substrate with a conductive film 40 in each of Example 1 and Comparative Example 1. In FIG. 8, the horizontal axis represents binding energy (unit: eV) of photoelectrons, and the vertical axis represents intensity (signal count/second). In the B1s narrow spectrum, binding energy of a peak corresponding to a bond between B and O is near the dotted line on the left side of FIG. 8 (about 193 eV), and binding energy of a peak corresponding to a bond between B and Ta is near the dotted line on the right side of FIG. 8 (about 188 eV).

As illustrated in FIG. 8, the B1s narrow spectrum of the outermost layer 46 in Example 1 has a maximum peak at binding energy of 190 eV or more and 195 eV or less, and has no peak at binding energy of 185 eV or more and less than 190 eV. On the other hand, the B1s narrow spectrum of the outermost layer 46 in Comparative Example 1 has a maximum peak at binding energy of 185 eV or more and less than 190 eV. The B1s narrow spectrum of the outermost layer 46 in Comparative Example 1 has a peak at binding energy of 190 eV or more and 195 eV or less, but the intensity thereof is smaller than that of the peak at binding energy of 185 eV or more and less than 190 eV.

As illustrated in FIG. 8, the B1s narrow spectrum of the conductive layer 44 of each of Example 1 and Comparative Example 1 has a maximum peak at binding energy of 185 eV or more and less than 190 eV. The conductive layer 44 and the outermost layer 46 in each of Example 2 and Comparative Example 2 were also analyzed similarly by the XPS method. Table 1 presents appearances of peaks in the B1s narrow spectra of the conductive film 42 and the outermost layer 46 of the substrate with a conductive film 40 in each of Examples 1 and 2 and Comparative Examples 1 and 2.

### <Hydrogen Content of Conductive Layer 44>

The substrate with a conductive film 40 in each of Examples and Comparative Examples was subjected to hydrogen exposure treatment assuming an environment of an exposure machine, and a hydrogen content in the conductive layer 44 after the treatment was measured using secondary ion mass spectrometry (SIMS). Similarly to the above-described internal analysis by the XPS method, the conductive film 42 was dug by about 10 nm by Ar gas sputtering, and the hydrogen content of the conductive film 42 (conductive layer 44) in the dug region was measured by the SIMS method. The measurement result of the hydrogen content is presented in the column of “Hydrogen content (at %) of conductive layer” in Table 1. The lower the hydrogen content of the conductive layer 44, the higher the effect of suppressing incorporation of hydrogen into the conductive film 42 by the outermost layer 46.

As presented in Table 1, the hydrogen content of the conductive layer 44 in each of Examples 1 and 2 was smaller than the hydrogen content of the conductive layer 44 in each of Comparative Examples 1 and 2. Therefore, it can be said that the effect of suppressing incorporation of hydrogen into the conductive film 42 by the outermost layer 46 in each of Examples 1 and 2 is high.

### <Sheet Resistance of Conductive Film 42>

Sheet resistance of the conductive film 42 (conductive layer 44 and outermost layer 46) of the substrate with a conductive film 40 in each of Examples and Comparative Examples was measured by bringing an electrode into contact with a surface of the outermost layer 46 by a four-terminal measurement method. Table 1 presents the measurement results of the sheet resistance.

<Preparation of Substrate with a Multilayer Reflective Film 20>

Next, the substrate with a multilayer reflective film 20 in each of Examples 1 and 2 and Comparative Examples 1 and 2 was prepared. As the substrate 10, the same substrate as the substrate 10 used for manufacturing the above-described substrate with a conductive film 40 in each of Examples 1 and 2 and Comparative Examples 1 and 2 was used. The multilayer reflective film 21 was formed on a first main surface of the substrate 10.

The multilayer reflective film 21 of the substrate with a multilayer reflective film 20 in each of Examples and Comparative Examples was formed as follows. That is, using a Mo target and a Si target, a Mo layer (low refractive index layer, thickness: 2.8 nm) and a Si layer (high refractive index layer, thickness: 4.2 nm) were alternately layered (the number of stacked layers: 40 pairs) by an ion beam sputtering method to form the multilayer reflective film 21 on the above-described substrate 10.

After the multilayer reflective film 21 was formed, the protective film 22 (film thickness: 2.5 nm) made of Ru was further continuously formed on the multilayer reflective film 21 by an ion beam sputtering method to obtain the substrate with a multilayer reflective film 20.

Next, on a back surface of the substrate with a multilayer reflective film 20 where the multilayer reflective film 21 was not formed, the same conductive film 42 as in the case of the above-described substrate with a conductive film 40 in each of Examples 1 and 2 and Comparative Examples 1 and 2 was formed.

The substrate with a multilayer reflective film 20 in each of Examples 1 and 2 and Comparative Examples 1 and 2 was manufactured as described above.

### <Preparation of Reflective Mask Blank 100>

A TaBN film having a film thickness of 55 nm was formed as the absorber film 24 on the above-described protective film 22 of the substrate with a multilayer reflective film 20 in each of Examples and Comparative Examples by a magnetron sputtering (reactive sputtering) method. A composition of the absorber film 24 was Ta:B:N=75:12:13 (atomic ratio), and the absorber film 24 had a film thickness of 55 nm.

As described above, the reflective mask blank 100 in each of Examples and Comparative Examples was manufactured.

### <Reflective Mask 200>

Next, using the reflective mask blank 100 in each of Examples and Comparative Examples, the reflective mask 200 in each of Examples and Comparative Examples was manufactured. Manufacture of the reflective mask 200 will be described with reference to FIG. 6.

First, as illustrated in FIG. 6(A), the resist film 32 was formed on the absorber film 24 of the reflective mask blank 100. Then, a desired pattern such as a circuit pattern was drawn (exposed) on the resist film 32 and further developed and rinsed to form the predetermined resist pattern 32a (FIG. 6(B)). Next, using the resist pattern 32a as a mask, the absorber film 24 (TaBN film) was dry-etched using Cl₂ gas to form the absorber pattern 24a (FIG. 6(C)). Thereafter, the resist pattern 32a was removed (FIG. 6(D)).

Finally, wet cleaning was performed with deionized water (DIW) to manufacture the reflective mask 200 in each of Examples 1 and 2 and Comparative Examples 1 and 2.

### <Manufacture of Semiconductor Device>

The reflective mask 200 in each of Examples 1 and 2 and Comparative Examples 1 and 2 was set in an EUV scanner, and EUV exposure was performed on a wafer on which a film to be processed and a resist film were formed on the semiconductor substrate 60 which is a transferred object. Then, this resist film that had been subjected to exposure was developed to form a resist pattern on the semiconductor substrate 60 on which the film to be processed was formed.

In the reflective mask 200 in each of Examples 1 and 2, it is considered that diffusion of hydrogen into the conductive layer 44 was suppressed because the conductive film 42 includes the predetermined outermost layer 46. Therefore, by using the reflective mask 200 in each of Examples 1 and 2, a fine and highly accurate transfer pattern (resist pattern) could be formed on the semiconductor substrate 60 (transferred substrate). Meanwhile, the outermost layer 46 of the conductive film 42 of the reflective mask 200 in each of Comparative Examples 1 and 2 is not the predetermined outermost layer 46. Therefore, in the case of the reflective mask 200 in each of Comparative Examples 1 and 2, diffusion of hydrogen into the conductive layer 44 was not suppressed, and there was a problem that the flatness could not be maintained. Therefore, in the case of using the reflective mask 200 in each of Comparative Examples 1 and 2, it was not possible to form a fine and highly accurate transfer pattern (resist pattern) on the semiconductor substrate 60 (transferred substrate) as compared with the cases of Examples 1 and 2.

In the case where a semiconductor device was manufactured using the reflective mask 200 in each of Examples 1 and 2, a resist pattern was transferred onto the film to be processed by etching, and through various steps such as formation of an insulating film and a conductive film, introduction of a dopant, and annealing, a semiconductor device having desired characteristics could be manufactured at a high yield.

TABLE 1

| | | | Comparative | Comparative |
|---|---|---|---|---|
| | Example 1 | Example 2 | Example 1 | Example 2 |
| Conductive layer (film | TaB (64 nm) | TaB (64 nm) | TaB (64 nm) | TaB (64 nm) |
| thickness nm) | | | | |
| Conductive layer XPS | Maximum peak | Maximum peak | Maximum peak | Maximum peak |
| analysis: | | | | |
| binding energy of 185 | | | | |
| eV or more and less | | | | |
| than 190 eV | | | | |
| Conductive layer XPS | No peak | No peak | No peak | No peak |
| analysis: | | | | |
| binding energy of 190 | | | | |
| eV or more and 195 eV | | | | |
| or less | | | | |
| Outermost layer (film | TaBO (6 nm) | TaBO (4 nm) | — | TaO (6 nm) |
| thickness nm) | | | | |
| Outermost layer XPS | No peak | Having a peak | Maximum peak | No peak |
| analysis: | | | | |
| binding energy of 185 | | | | |
| eV or more and less | | | | |
| than 190 eV | | | | |
| Outermost layer XPS | Maximum peak | Maximum peak | Having a peak | No peak |
| analysis: | | | | |
| binding energy of 190 | | | | |
| eV or more and 195 eV | | | | |
| or less | | | | |
| Sheet resistance | 29.5 Ω/□ | 29.8 Ω/□ | 30.0 Ω/□ | 29.5 Ω/□ |
| Hydrogen content | Detection lower | Detection lower | 10.0 | 6.0 |
| (at %) of conductive | limit or less | limit or less | | |
| layer | | | | |

TABLE 2

| | | | Comparative | Comparative |
|---|---|---|---|---|
| | Example 1 | Example 2 | Example 1 | Example 2 |
| Target | TaB | TaB | — | Ta |
| Film forming gas | Ar and O₂ | Ar and O₂ | — | Ar and O₂ |
| Composition ratio (at %) | Ta:B:O = | Ta:B:O = | — | Ta:O = |
| of outermost layer | 36.3:1.4:62.3 | 41.0:1.6:57.4 | | 36.8:63.2 |

### REFERENCE SIGNS LIST

10 Substrate
20 Substrate with a multilayer reflective film
21 Multilayer reflective film
22 Protective film
24 Absorber film
24a Absorber pattern
25 Etching mask film
32 Resist film
32a Resist pattern
40 Substrate with a conductive film
42 Conductive film
44 Conductive layer
46 Outermost layer
50 EUV exposure apparatus
51 EUV light generation unit
52 Laser light source
53 Tin droplet generation unit
54 Catching unit
55 Collector
56 Irradiation optical system
57 Projection optical system
58 Reticle stage
59 Wafer stage
60 Semiconductor substrate
100 Reflective mask blank
200 Reflective mask

1. A substrate with a conductive film, comprising:
a substrate having two main surfaces; and
a conductive film disposed on one of the two main surfaces of the substrate,
wherein:
the conductive film comprises an outermost layer disposed on an outermost surface of the conductive film on a side opposite to the substrate, and a conductive layer disposed between the outermost layer and the substrate,
the outermost layer comprises a metal (M), boron (B), and oxygen (O), and
the outermost layer has a maximum peak at binding energy of 190 eV or more and 195 eV or less in a B1s narrow spectrum obtained by analysis by X-ray photoelectron spectroscopy.

2. The substrate with a conductive film according to claim 1, wherein a detection depth of the binding energy of the X-ray photoelectron spectroscopy in the outermost layer is about 4 nm to about 5 nm.

3. The substrate with a conductive film according to claim 1, wherein the outermost layer has a peak binding energy at values other than 185 eV or more and less than 190 eV in the B1s narrow spectrum obtained by analysis by the X-ray photoelectron spectroscopy.

4. The substrate with a conductive film according to claim 1, wherein a content of boron (B) in the outermost layer is 0.5 at % to 25 at %.

5. The substrate with a conductive film according to claim 1, wherein the conductive layer comprises the metal (M) and boron (B).

6. The substrate with a conductive film according to claim 1, wherein the conductive layer has a maximum peak at binding energy of 185 eV or more and less than 190 eV in the B1s narrow spectrum obtained by analysis by the X-ray photoelectron spectroscopy.

7. The substrate with a conductive film according to claim 1, wherein the metal (M) is at least one selected from Ta, Cr, Pt, Au, Rh, Ru, Ir, and Hf.

8. A reflective mask blank comprising:
a substrate having two main surfaces;
a conductive film disposed on one of the two main surfaces of the substrate;
a multilayer reflective film disposed on the other of the two main surfaces of the substrate; and
an absorber film disposed on the multilayer reflective film, wherein
the conductive film comprises an outermost layer disposed on an outermost surface of the conductive film on a side opposite to the substrate, and a conductive layer disposed between the outermost layer and the substrate,
the outermost layer comprises a metal (M), boron (B), and oxygen (O), and
the outermost layer has a maximum peak at binding energy of 190 eV or more and 195 eV or less in a B1s narrow spectrum obtained by analysis by X-ray photoelectron spectroscopy.

9. The reflective mask blank according to claim 8, wherein a detection depth of the binding energy of the X-ray photoelectron spectroscopy in the outermost layer is about 4 nm to about 5 nm.

10. The reflective mask blank according to claim 8, wherein the outermost layer has a peak at binding energy at values other than 185 eV or more and less than 190 eV in the B1s narrow spectrum obtained by analysis by the X-ray photoelectron spectroscopy.

11. The reflective mask blank according to claim 8, wherein a content of boron (B) in the outermost layer is 0.5 at % to 25 at %.

12. The reflective mask blank according to claim 8, wherein the conductive layer comprises the metal (M) and boron (B).

13. The reflective mask blank according to claim 8, wherein the conductive layer has a maximum peak at binding energy of 185 eV or more and less than 190 eV in the B1s narrow spectrum obtained by analysis by the X-ray photoelectron spectroscopy.

14. The reflective mask blank according to claim 8, wherein the metal (M) is at least one selected from Ta, Cr, Pt, Au, Rh, Ru, Ir, and Hf.

15. A reflective mask comprising:
a substrate having two main surfaces;
a conductive film disposed on one of the two main surfaces of the substrate;
a multilayer reflective film disposed on the other of the two main surfaces of the substrate; and
an absorber pattern disposed on the multilayer reflective film, wherein
the conductive film comprises an outermost layer disposed on an outermost surface of the conductive film on a side opposite to the substrate, and a conductive layer disposed between the outermost layer and the substrate,
the outermost layer comprises a metal (M), boron (B), and oxygen (O), and
the outermost layer has a maximum peak at binding energy of 190 eV or more and 195 eV or less in a B1s narrow spectrum obtained by analysis by X-ray photoelectron spectroscopy.

16. The reflective mask according to claim 15, wherein a detection depth of the binding energy of X-ray photoelectron spectroscopy in the outermost layer is about 4 nm to about 5 nm.

17. The reflective mask according to claim 15, wherein the outermost layer has a peak at binding energy at values other than 185 eV or more and less than 190 eV in the B1s narrow spectrum obtained by analysis by the X-ray photoelectron spectroscopy.

18. The reflective mask according to claim 15, wherein a content of boron (B) in the outermost layer is 0.5 at % to 25 at %.

19. The reflective mask according to claim 15, wherein the conductive layer comprises the metal (M) and boron (B).

20. The reflective mask according to claim 15, wherein the conductive layer has a maximum peak at binding energy of 185 eV or more and less than 190 eV in the B1s narrow spectrum obtained by analysis by the X-ray photoelectron spectroscopy.

21. The reflective mask according to claim 15, wherein the metal (M) is at least one selected from Ta, Cr, Pt, Au, Rh, Ru, Ir, and Hf.

22. (canceled)
